(19) United States
(12) Patent Application Publication
(10) Pub. No.: US 2025/0246492 A1
(43) Pub. Date: Jul. 31, 2025

(54) IC PACKAGE WITH INTERCONNECT

(71) Applicant: TEXAS INSTRUMENTS INCORPORATED, DALLAS, TX (US)

(72) Inventors: GUANGXU LI, ALLEN, TX (US); JONATHAN ALMERIA NOQUIL, PLANO, TX (US); SYLVESTER ANKAMAH-KUSI, McKINNEY, TX (US); RAJEN MANICON MURUGAN, DALLAS, TX (US); ENIS TUNCER, DALLAS, TX (US)

(21) Appl. No.: 18/427,207

(22) Filed: Jan. 30, 2024

(51) Int. Cl. H01L 23/31; H01L 23/00; H01L 23/495; H01L 25/065

(52) U.S. Cl. CPC H01L 23/3114; H01L 23/4951; H01L 23/4952; H01L 24/08; H01L 24/16; H01L 25/0657; H01L 2224/0801; H01L 2224/08145; H01L 2224/16104; H01L 2224/16145; H01L 2225/06517; H01L 2225/06586; H01L 2924/01029; H01L 2924/01079; H01L 2924/182

(57) ABSTRACT

An IC (integrated circuit) package includes an interconnect. The interconnect includes a substrate having a planar surface with pads and studs extending in a direction normal to the planar surface. The IC package also includes a die having bond pads coupled to the pads of the substrate. The IC package includes a mold compound encapsulating the substrate, the die and a portion of the interconnect.

### TECHNICAL FIELD

This description relates to an IC (integrated circuit) package that includes a die mounted on an interconnect.

### BACKGROUND

Delamination in an IC (integrated circuit) package refers to the phenomenon where layers within the package, which are normally bonded together, start to separate or split apart. This separation can occur between various layers such as a die and a substrate, between the substrate and an encapsulant (e.g., mold compound) or within the layers of the substrate. In some examples, delamination disrupts internal connections and impairs functionality of the IC package.

### SUMMARY

A first example relates to an IC (integrated circuit) package including an interconnect. The interconnect includes a substrate having a planar surface with pads and studs extending in a direction normal to the planar surface. The IC package also includes a die having bond pads coupled to the pads of the substrate. The IC package includes a mold compound encapsulating the substrate, the die and a portion of the interconnect.

A second example relates to an IC package that includes an interconnect. The interconnect includes a substrate having a planar surface with pads and elevated traces extending from the planar surface. The IC package also includes a die with bond pads, and copper posts extending from the bond pads of the die to the elevated traces and the copper posts. The IC package further includes a mold compound encapsulating die, the copper posts and a portion of the interconnect.

A third example relates to a method for forming an IC package including mounting a die with bond pads on an interconnect. The interconnect includes a substrate having a planar surface with pads and studs extending in a direction normal to the planar surface. The die is mounted such that the bond pads are coupled to the pads of the substrate. The bond pads are between at least two studs of the studs of the interconnect. The method also includes reflowing solder overlaying the pads of the substrate and encapsulating the die and a portion of the interconnect in a mold compound.

### BRIEF DESCRIPTION OF THE DRAWINGS

FIG. 1 illustrates a first example of an IC package with studs to curtail delamination between the layers of the IC package.

FIGS. 2A and 2B illustrate an overhead view of an IC package that is employable to implement the IC package of FIG. 1.

FIG. 3 illustrates a second example of an IC package with studs to curtail delamination between the layers of the IC package.

FIGS. 4A and 4B illustrate an overhead view of an IC package that is employable to implement the IC package of FIG. 3.

FIG. 5 illustrates a third example IC package with studs to curtail delamination between the layers of the IC package.

FIGS. 6A and 6B illustrate an overhead view of an IC package that is employable to implement the IC package of FIG. 5.

FIG. 7 illustrates a fourth example IC package with elevated traces and studs to curtail delamination between the layers of the IC package.

FIGS. 8A and 8B illustrate an overhead view of an IC package that is employable to implement the IC package of FIG. 7.

FIG. 9A illustrates a first view of the conventional IC package with a crack.

FIG. 9B illustrates a second view of the conventional IC package after the crack has expanded.

FIG. 10A illustrates a first stress chart for a conventional IC package.

FIG. 10B illustrates a second stress chart for an instance of the fourth example of the IC package of FIG. 7.

FIGS. 11-17 illustrates stages of a method for fabricating an IC package.

FIGS. 18-25 illustrates stages of another method for fabricating an IC package.

FIG. 26 illustrates a flowchart of an example method for forming an IC package.

### DETAILED DESCRIPTION

This description relates to an IC (integrated circuit) package that includes an interconnect with a substrate having a planar surface with pads. In some examples, the interconnect includes studs extending in a direction normal to the planar surface. Additionally or alternatively, the interconnect includes elevated traces that extend normal to the planer surface of the substrate. A die having bond pads is coupled to the pads of the substrate. In some examples, the bond pads are between at least two studs of the studs of the interconnect. In some examples, copper posts extending from the bond pads are encircled by the studs. In other examples, the studs or the copper posts are omitted. A mold compound encapsulates the substrate, the die and a portion of the interconnect. The studs and/or the elevated traces curtail expansion of cracks that could otherwise cause delamination.

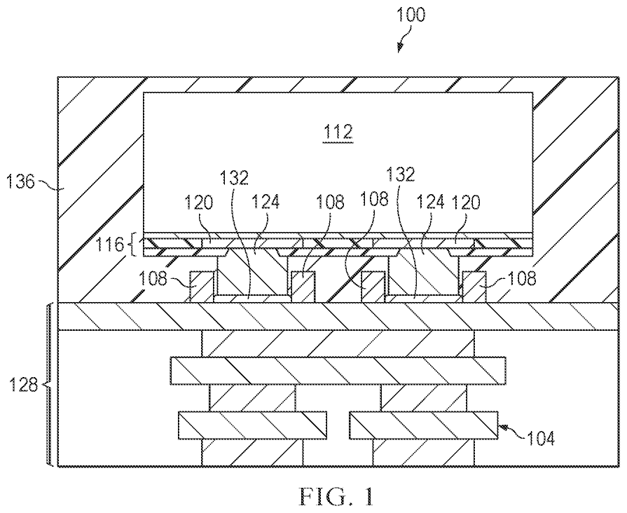

FIG. 1 illustrates a first example of an IC package 100 (hereinafter, “the first example”) that includes an interconnect 104 (e.g., a lead frame) with studs 108 to curtail delamination between the layers of the IC package 100. The IC package 100 includes a die 112 that includes embedded circuitry. In some examples, the IC package 100 is a quad flat no-leads (QFN) package or a dual flat no-leads (DFN) package. The die 112 also includes a metTop layer 116 (e.g., a metallization layer) that provides metal pads that includes bond pads 120. Copper posts 124 are formed on the bond pads 120. The copper posts 124 extend to pads on a substrate 128 of the interconnect 104. The copper posts 124 are attached to the pads on the substrate 128 with solder 132 (e.g., solder paste). The die 112, the copper posts 124 and a portion of the interconnect 104 are encapsulated in a mold compound 136.

The substrate 128 forms a planer surface, and the studs 108 extend in a direction normal to the planer surface of the substrate 128. That is, the studs 108 are protrusions from the planer surface of the substrate 128. In some examples, the studs 108 have a circular shape, such that the studs 108 have a rectangular cross-section. In some such examples, the studs 108 have a hollow shape to encircle the copper posts 124.

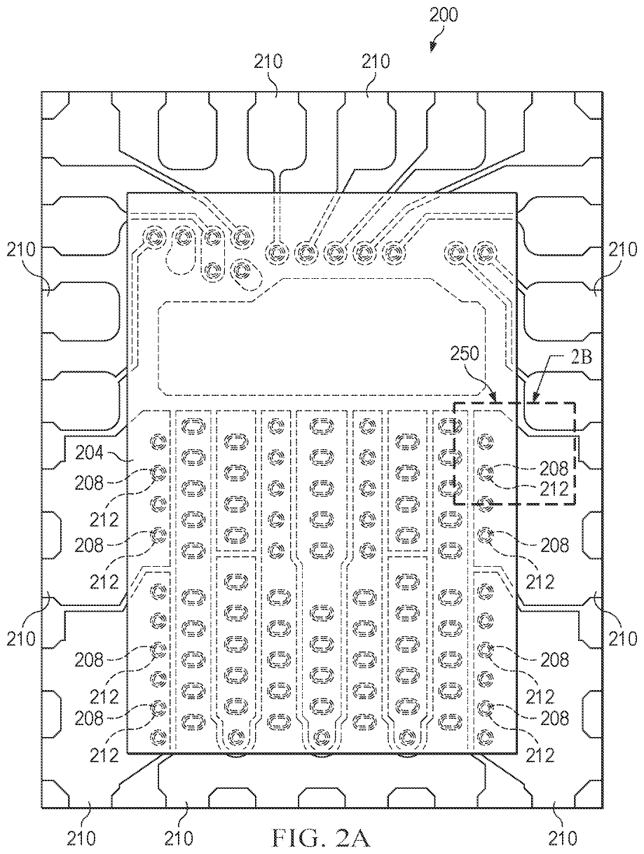

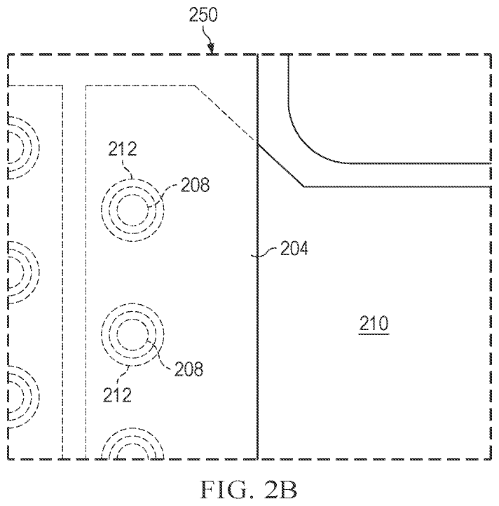

The studs 108 are implemented as circular fences that encircle the copper posts 124. FIGS. 2A and 2B illustrate an overhead view of an IC package 200 that is employable to implement the IC package 100 of FIG. 1. In FIG. 2A, the IC package 200 includes a die 204 with copper posts 208 (only some of which are labeled) mounted on an interconnect 210. The copper posts 208 are encircled by corresponding studs 212. FIG. 2B illustrates an expanded region 250 (e.g., a zoomed-in region) of the IC package 200.

Referring back to FIG. 1, the studs 108 on the interconnect 104 impede the spreading of cracks. More particularly, the studs 108 impede the spreading of cracks between the mold compound 136 and traces in the interconnect 104 that are coupled to the pads of the substrate 128 during temperature cycling. For instance, if a crack were to develop in a region encircled by one of the studs 108, including a crack proximate to a portion of the solder 132, the crack would be impeded from expanding beyond the corresponding stud 108, thereby curtailing chances of delamination of the layers of the IC package 100, which could cause an open circuit and subsequent failure of the IC package 100. Thus, inclusion of the studs 108 improves reliability of the IC package 100.

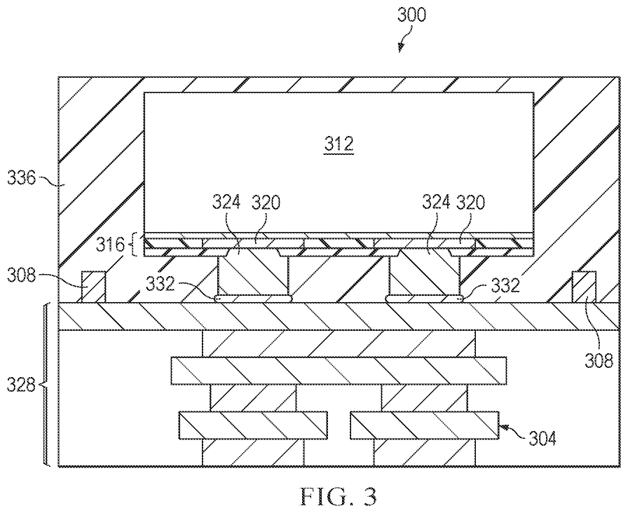

FIG. 3 illustrates a second example of an IC package 300 (hereinafter, “the second example”). The second example is an alternative design of IC package 300 that includes an interconnect 304 (e.g., a lead frame) with studs 308 to curtail delamination between the layers of the IC package 300. The IC package 300 includes a die 312 that includes embedded circuitry. In some examples, the IC package 300 is a QFN IC package or a DFN IC package. The die 312 also includes a metTop layer 316 (e.g., a metallization layer) providing metal pads that include bond pads 320. Copper posts 324 are formed on the bond pads 320. The copper posts 324 extend to pads on a substrate 328 of the interconnect 304. The copper posts 324 are attached to the pads on the substrate 328 with solder 332 (e.g., solder paste). The die 312, the copper posts 324 and a portion of the interconnect 304 are encapsulated in a mold compound 336. The substrate 328 has a planer surface, and the studs 308 extend in a direction normal to the planer surface of the substrate 328.

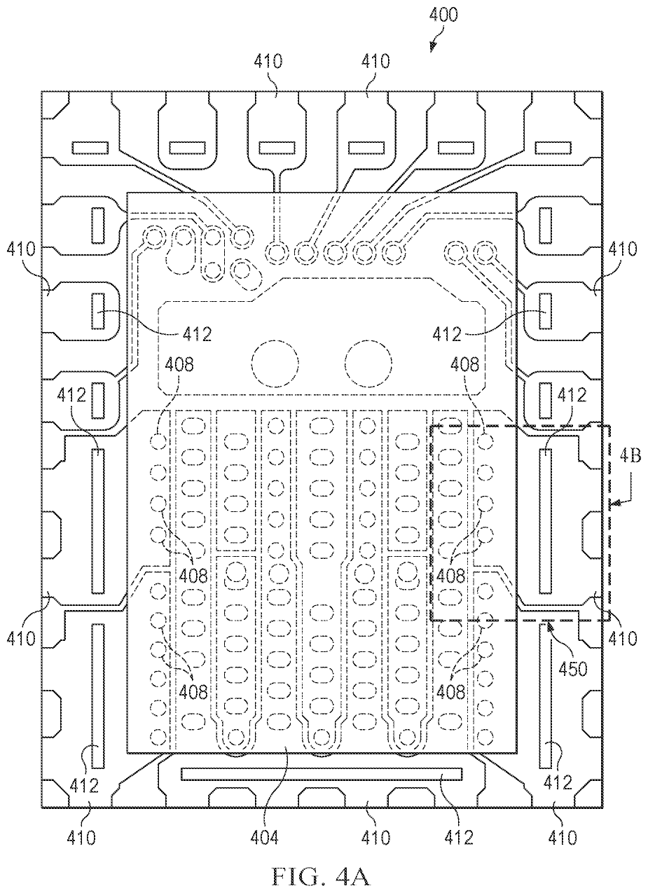

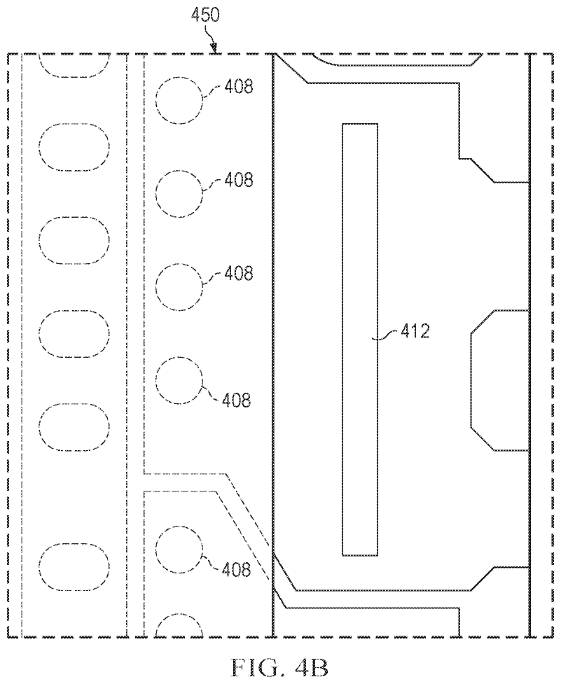

The studs 308 are proximate a periphery of the interconnect 304, and distal to the copper posts 324. The studs 308 are arranged as a segmented barrier (e.g., a segmented fence) around the interconnect 304. FIGS. 4A and 4B illustrate an overhead view of an IC package 400 that is employable to implement the IC package 300 of FIG. 3. In FIG. 4A, the IC package 400 includes a die 404 with copper posts 408 (only some of which are labeled) mounted on an interconnect 410. The copper posts 408 are distal from and circumscribed by corresponding studs 412. Moreover, as illustrated, there are multiple copper posts 408 between studs 412, such that a given copper post 408 is between a set of two or more studs 412. Stated differently, there are multiple copper posts 408 between segments of the barrier formed by the studs 412. FIG. 4B illustrates an expanded region 450 (e.g., a zoomed-in region) of the IC package 400.

Referring back to FIG. 3, the studs 308 on the interconnect 304 impede the spreading of cracks. More particularly, the studs 308 impede the spreading of cracks between the mold compound 336 and traces in the interconnect 304 that are coupled to the pads of the substrate 328 during temperature cycling. For instance, if a crack were to develop in a region outside the barrier formed by the studs 308, the crack would be impeded from expanding beyond the corresponding stud 308 and toward the copper posts 324, thereby curtailing chances of delamination of the layers of the IC package 300, which could cause an open circuit and subsequent failure of the IC package 300. Thus, inclusion of the studs 308 improves reliability of the IC package 300.

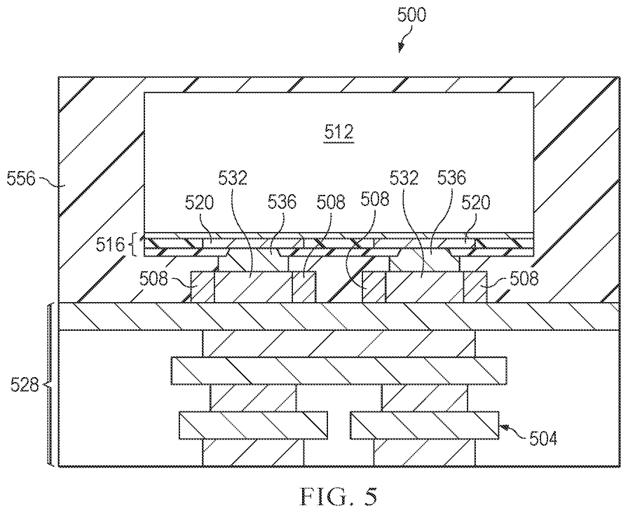

FIG. 5 illustrates a third example IC package 200 (hereinafter, “the third example”). The third example is an alternative low-cost design of IC package 500 that includes an interconnect 504 (e.g., a lead frame) with studs 508 to curtail delamination between the layers of the IC package 500. The IC package 500 includes a die 512 that includes embedded circuitry. In some examples, the IC package 500 is a QFN IC package or a DFN IC package. The die 512 also includes a metTop layer 516 (e.g., a metallization layer) that provides metal pads that include bond pads 520.

The interconnect 504 includes a substrate 528. The studs 508 encircle a cavity filled with solder 532, which can alternatively be referred to as a solder reservoir. The bond pads 520 are coupled with the solder 532 using ENEPIG (electroless nickel electroless palladium immersion gold) material 536 that is applied to the bond pads 520, avoiding the need for copper posts. The substrate 528 has a planer surface, and the studs 508 extend in a direction normal to the planer surface of the substrate 528. In the example illustrated, the studs 508 have a hollow circular shape to form the cavity for the solder 532. The die 512, the ENEPIG material 536 and a portion of the interconnect 504 are encapsulated in a mold compound 556. The ENEPIG material 536 is applied to the bond pads 520 without electrolysis.

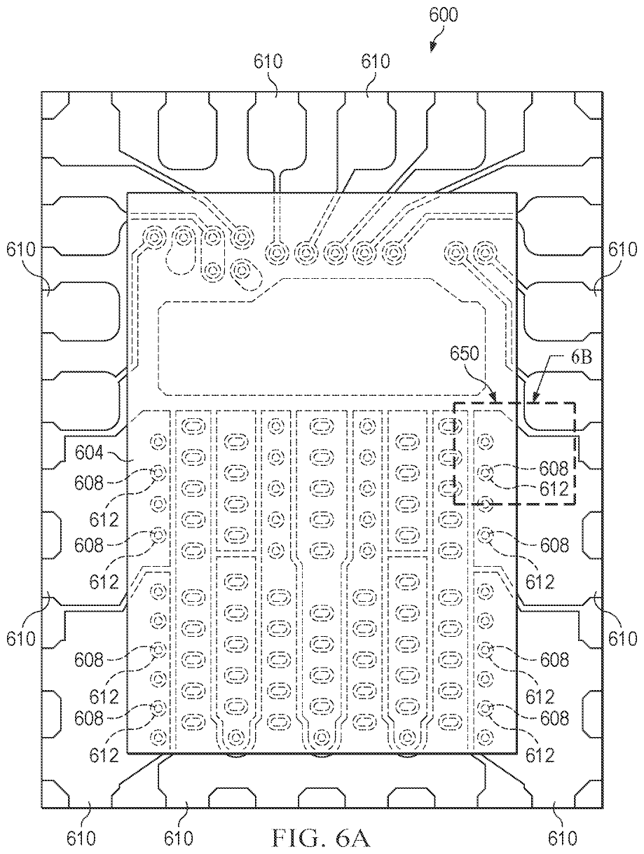

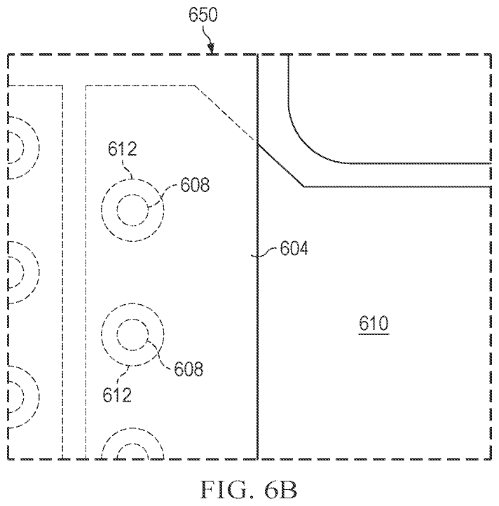

The studs 508 are provided to form the cavities for the solder 532. FIGS. 6A and 6B illustrate an overhead view of an IC package 600 that is employable to implement the IC package 500 of FIG. 5. In FIG. 6A, the IC package 600 includes a die 604 with solder 608 filling cavities (only some of which are labeled) formed with studs 612 extended in a direction normal from a planer surface of an interconnect 610. FIG. 6B illustrates an expanded region 650 (e.g., a zoomed-in region) of the IC package 500.

Referring back to FIG. 5, the studs 508 on the interconnect 504 impede the spreading of cracks. More particularly, the studs 508 impede the spreading of cracks between the mold compound 556 and traces in the interconnect 504 that are coupled to the pads of the substrate 528 during temperature cycling. For instance, if a crack were to develop in a region outside the barrier formed by the studs 508, the crack would be impeded from expanding beyond the corresponding stud 508 and into the solder 532, thereby curtailing chances of delamination of the layers of the IC package 500, which could cause an open circuit and subsequent failure of the IC package 500. Thus, inclusion of the studs 508 improves reliability of the IC package 500.

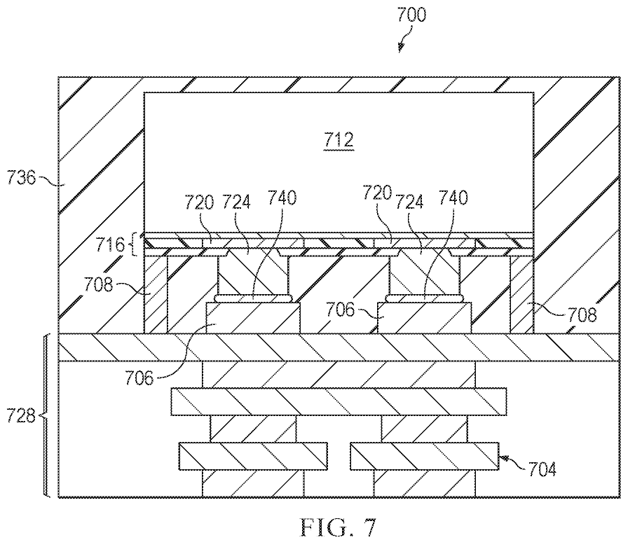

FIG. 7 illustrates a fourth example IC package 700 (hereinafter “the fourth example”) that includes an interconnect 704 (e.g., a lead frame) with elevated traces 706 and studs 708 to curtail delamination between the layers of the IC package 700. In some instances of the fourth example IC package 700, the studs 708 are omitted. The IC package 700 includes a die 712 that includes embedded circuitry. In some examples, the IC package 700 is a QFN IC package or a DEN IC package. The die 712 also includes a metTop layer 716 (e.g., a metallization layer) that provides metal pads that include bond pads 720. Copper posts 724 are formed on the bond pads 720. The copper posts 724 and the elevated traces 706 are on a substrate 728 of the interconnect 704. The copper posts 724 are attached to the elevated traces 706 with solder 740 (e.g., solder paste). The die 712, the copper posts 724 and a portion of the interconnect 704 are encapsulated in a mold compound 736.

The substrate 728 forms a planer surface, such that the elevated traces 706 and the studs 708 extend in a direction normal to the planer surface of the substrate 128. That is, the elevated traces 706 and the studs 708 are protrusions from the planer surface of the substrate 728. In some examples, the studs 708 are rectangular posts, and the elevated traces 706 have a circular shape. In other examples, other shapes are employed.

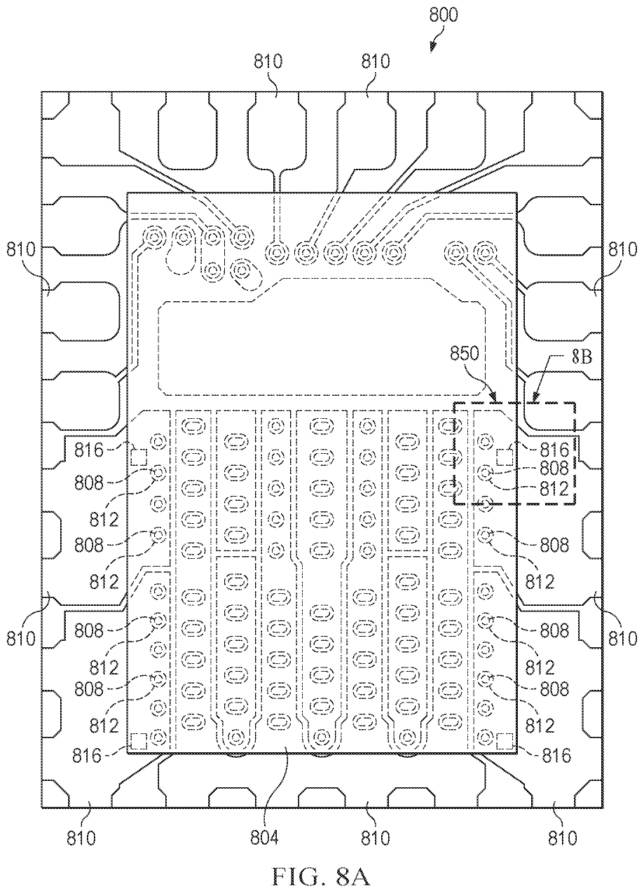

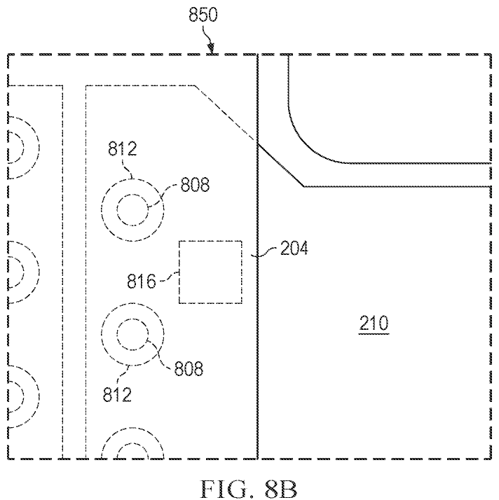

The studs 708 are proximate an edge of the die 712. FIGS. 8A and 8B illustrate an overhead view of an IC package 800 that is employable to implement the IC package 800 of FIG. 7. In FIG. 8A, the IC package 800 includes a die 804 with copper posts 808 (only some of which are labeled) mounted on an interconnect 810. The copper posts 808 are mounted on corresponding elevated traces 812. Studs 816 are located proximate edges of the die. In the example illustrated the studs 816 are proximate to the four corners of the studs 816, but in other examples, there are more or less studs 816. FIG. 8B illustrates an expanded region 850 (e.g., a zoomed-in region) of the IC package 200. As is illustrated in FIG. 8B, the elevated traces 812 are larger than the copper posts 808. In some examples where the copper posts 808 and the elevated traces 812 are circular, the corresponding elevated traces 812 have a diameter that extends by about 25 micrometers beyond an edge of the copper posts 808 on each side. Moreover, FIG. 8B illustrates a stud 816 spaced apart from the copper posts 808 and the corresponding elevated traces 812.

Referring back to FIG. 7, the elevated traces 706 and the studs 708 on the interconnect 704 impede the spreading of cracks. More particularly, the studs 708 impede the spreading of cracks between the mold compound 736 and traces in the interconnect 704 that are coupled to the pads of the substrate 728 during a temperature cycle. For instance, if a crack were to develop in a region encircled by one of the studs 708, including a crack proximate to a portion of the solder 740, the crack would be impeded from expanding beyond the corresponding stud 708, thereby curtailing chances of delamination of the layers of the IC package 700, which could cause an open circuit and subsequent failure of the IC package 700. Thus, inclusion of the elevated traces 706 and the studs 708 improves reliability of the IC package 700. Additionally, the elevated traces 706 and the studs 708 operate in concert to curtail movement of the die 712 due to uneven downward force on the die 712.

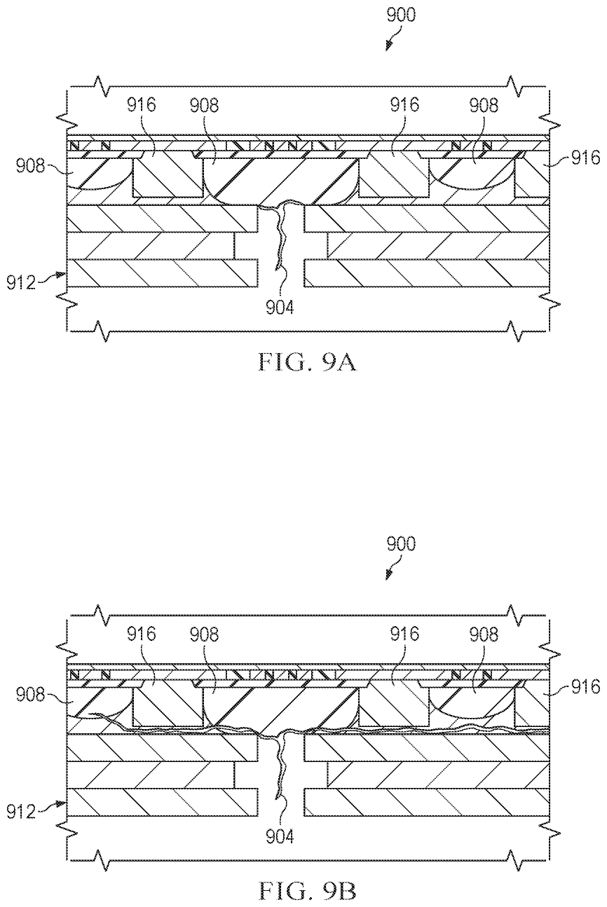

FIGS. 9A and 9B illustrate a conventional IC package 900 with an expanding crack 904. For simplification, FIGS. 9A and 9B employ the same reference numbers to denote the same structures. FIG. 9A illustrates a first view of the conventional IC package 900 wherein the crack 904 is formed in a mold compound 908, and the crack 904 spreads up to an interconnect 912. The IC package 900 omits features such as studs (e.g., the studs 108 of FIG. 1) and/or elevated traces (e.g., the elevated traces 706 of FIG. 7).

FIG. 9B illustrates a second view of the conventional IC package 900 after the crack 904 has expanded (e.g., after a temperature cycle). The conventional IC package 900 includes copper posts 916 that are separated from the interconnect 912 by the crack 904. Thus, the crack 904 causes delamination of the conventional IC package 900.

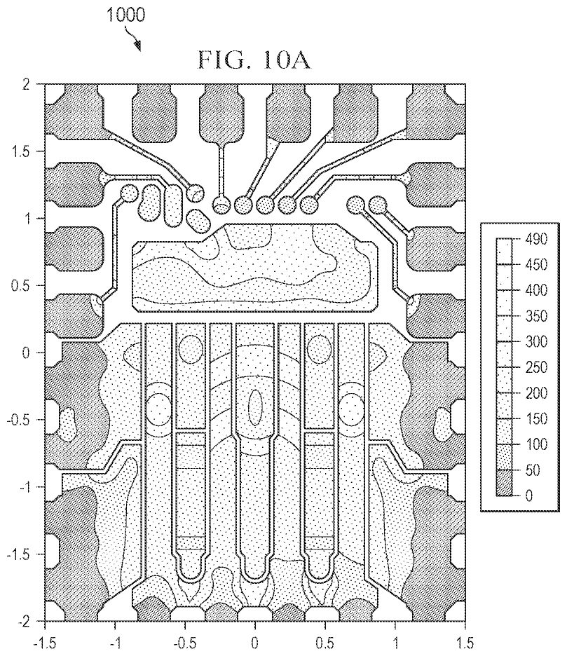

FIG. 10A illustrates a first stress chart 1000 for a conventional IC package, such as the conventional IC package 900 illustrated in FIGS. 9A and 9B. The IC package illustrated in FIG. 9A omits features such as studs and/or elevated traces. As demonstrated in the chart 1000, a center region of the IC package has an elevated stress relative to a periphery of the IC package. This stress can lead to spreading of a crack, which can ultimately lead to delamination.

FIG. 10B illustrates a second stress chart 1040 for an instance of the fourth example of the IC package 700 of FIG. 7. That is, the IC package demonstrated in the second stress chart 1040 has both elevated traces (e.g., the elevated traces 706 of FIG. 7) and studs (e.g., the studs 708 of FIG. 7). As illustrated by the second stress chart 1040, the IC package has a reduced stress in a center region compared the conventional IC package characterized in the first stress chart 1000.

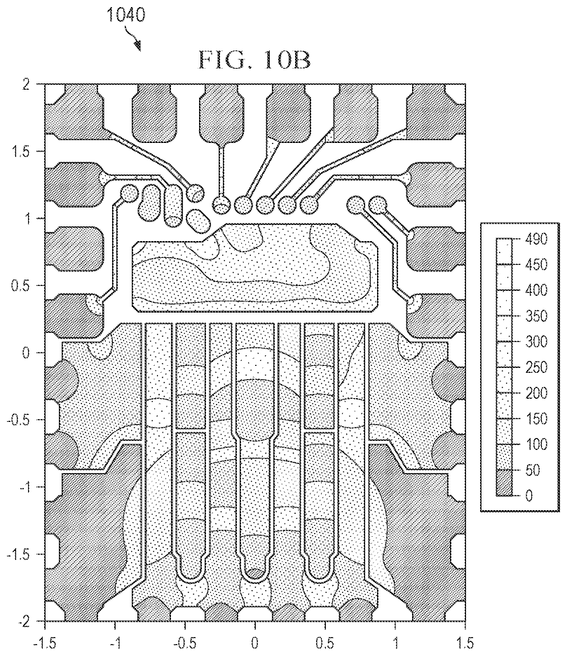

FIGS. 11-17 illustrates stages of a method for fabricating an IC package, such as the first example IC package 100 of FIG. 1, the second example IC package 300 of FIG. 3 and/or the fourth example IC package 700 of FIG. 7. Thus, FIGS. 11-17 employ the same reference numbers to denote the same structures.

In a first stage 1100 of the method, as illustrated in FIG. 11, a wafer 1200 is provided. The wafer 1200 includes K number of dies, including a first die 1204 and a Kth die 1208, where K is an integer greater than or equal to one. The K number of dies include circuitry to execute a specific operation.

The first die 1204 and the Kth die 1208 have a metTop layer 1212 formed thereon. The metTop layer 1212 is formed, for example, by Physical Vapor Deposition (PVD), Chemical Vapor Deposition (CVD) or electroplating and patterning and etching (e.g., with a photoresist). The metTop layer 1212 is formed of metal pads, and these metal pads include bond pads 1216 that are conductively coupled to internal circuits of the K number of die, including the first die 1204 and the Kth die 1208.

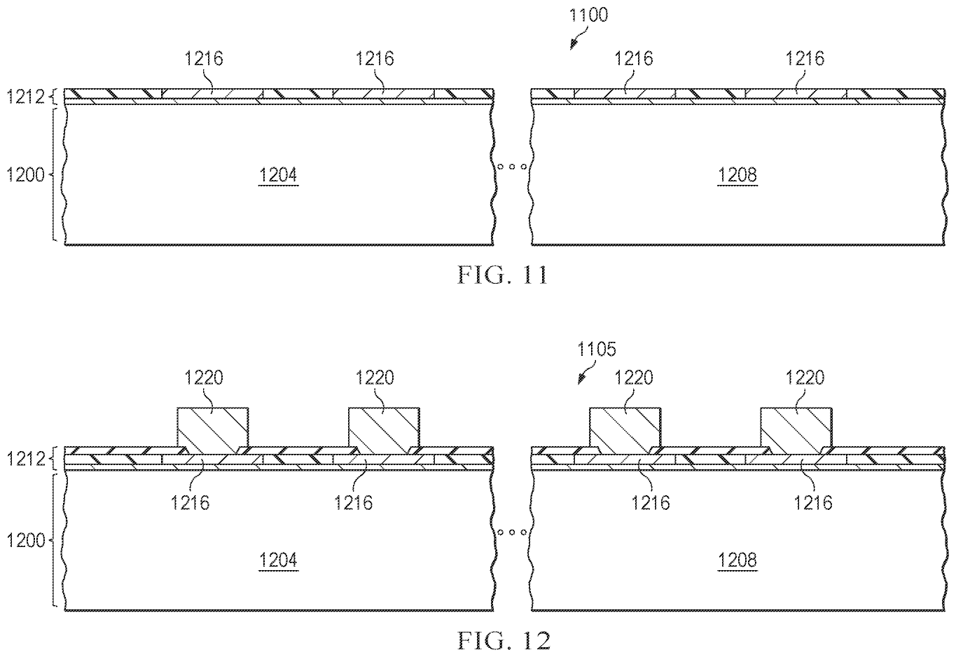

In a second stage 1105 of the method, as illustrated in FIG. 12, copper posts 1220 are formed on the bond pads 1216 of the K number of dies, including the first die 1204 and the Kth die 1208. The copper posts 1220 are formed, for example, with an electroplating operation. The copper posts 1220 enable a conductive connection to circuit components of the K number of dies.

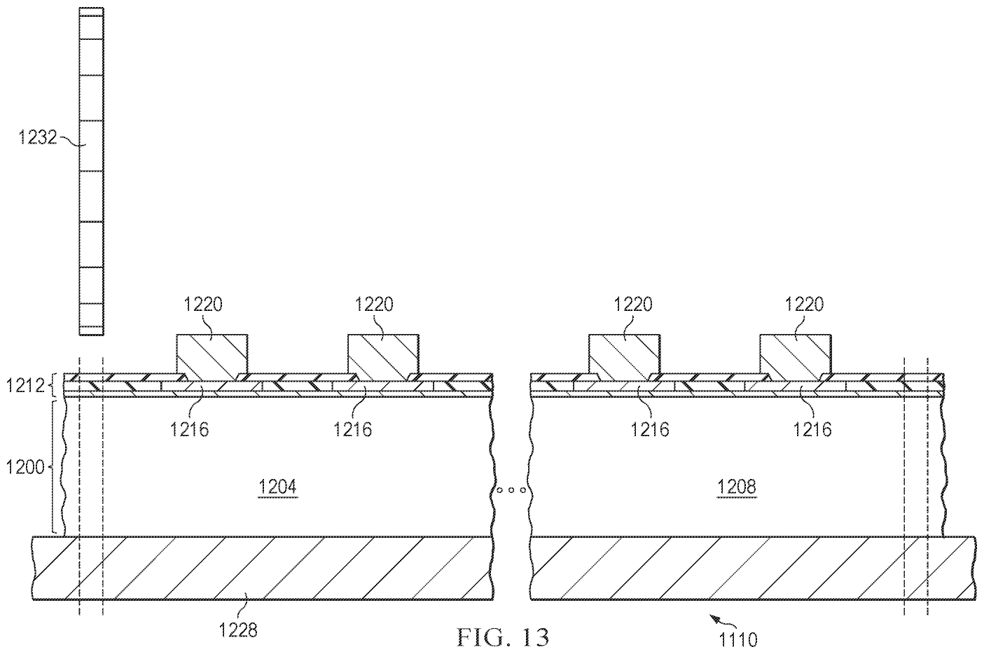

In a third stage 1110 of the method, as illustrated in FIG. 13, the wafer 1200 is placed on a dicing table 1228. Additionally, in the third stage 1110, a saw 1232, such as a laser saw, a diamond saw or a plasma cutter dices the wafer 1200 to singulate the K number of dies, including the first die 1204 and the Kth die 1208.

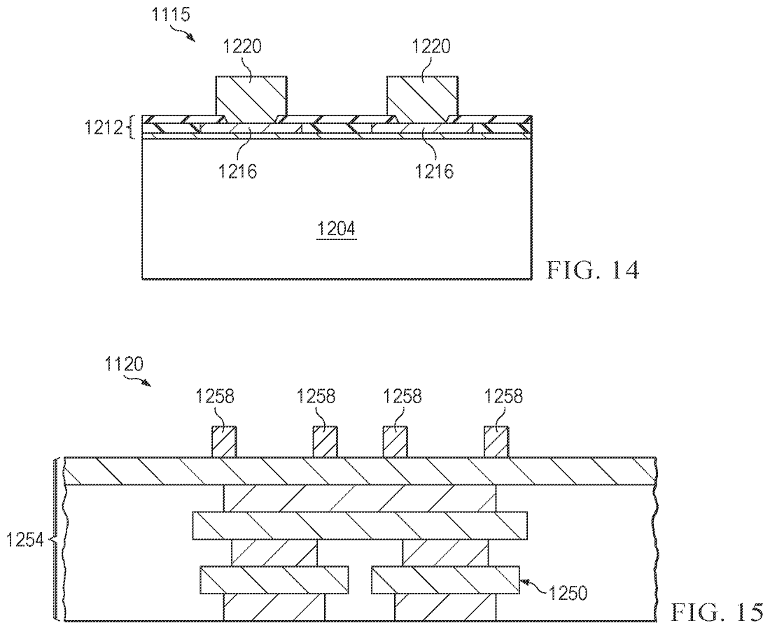

In a fourth stage 1115 of the method, as illustrated in FIG. 14, the first die 1204 is provided in response to the singulation. In a fifth stage 1120, as illustrated in FIG. 15, an interconnect 1250 is provided. The interconnect 1250 includes a substrate 1254 with pads for mounting the copper posts 1220. The substrate 1254 provides a planer surface. Additionally, the interconnect 1250 includes studs 1258 that extend in a direction normal from the planer surface of the substrate 1254. In examples such as the first example, the studs 1258 encircle a pad. In examples such as the second and fourth examples, the studs 1258 are proximate to a periphery of the interconnect 1250 and/or distal to the pads on the substrate 1254.

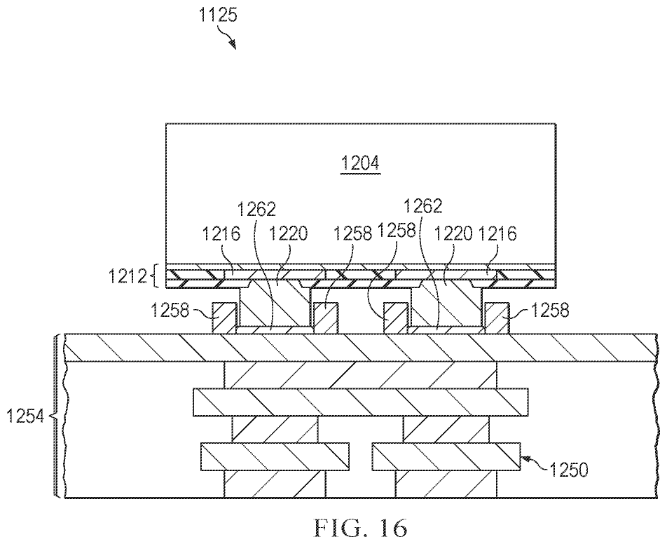

In a sixth stage 1125 of the method, as illustrated in FIG. 16, the copper posts 1220 are mounted on the substrate 1254. More particularly, the copper posts 1220 are attached to the substrate 1254 (e.g., on pads of the substrate 1254). The copper posts 1220 are attached to the substrate 1254 with solder 1262 (e.g., solder paste). In some examples, the solder 1262 is reflowed to adhere the bond pads 1216 to the substrate 1254. In examples, such as the fourth example, the copper posts 1220 are attached to elevated traces in a similar manner.

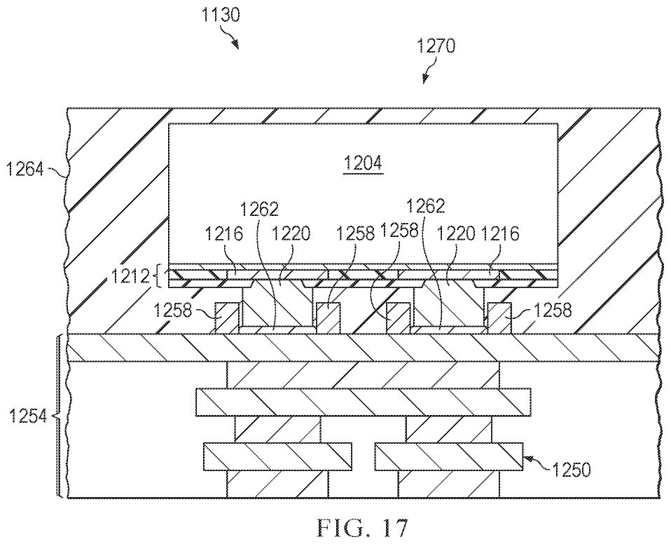

In a seventh stage 1130 of the method, as illustrated in FIG. 17, a mold compound 1264 is flowed over the first die 1204, the copper posts 1220 and the interconnect 1250 in a mold flow operation. The mold compound 1264 encapsulates the first die 1204, the copper posts 1220 and a portion of the interconnect 1250, leaving leads exposed. This forms an IC package 1270, which is employable to implement the first example IC package 100 of FIG. 1. Additionally, with some modifications, the IC package 1270 is employable to implement the second example IC package 300 of FIG. 3 or the fourth example IC package 700 of FIG. 7. Thus, in some examples, the IC package 1270 is a QFN IC package or a DFN IC package. The studs 1258 prevent spreading of a crack to avoid delamination of layers in the IC package 1270.

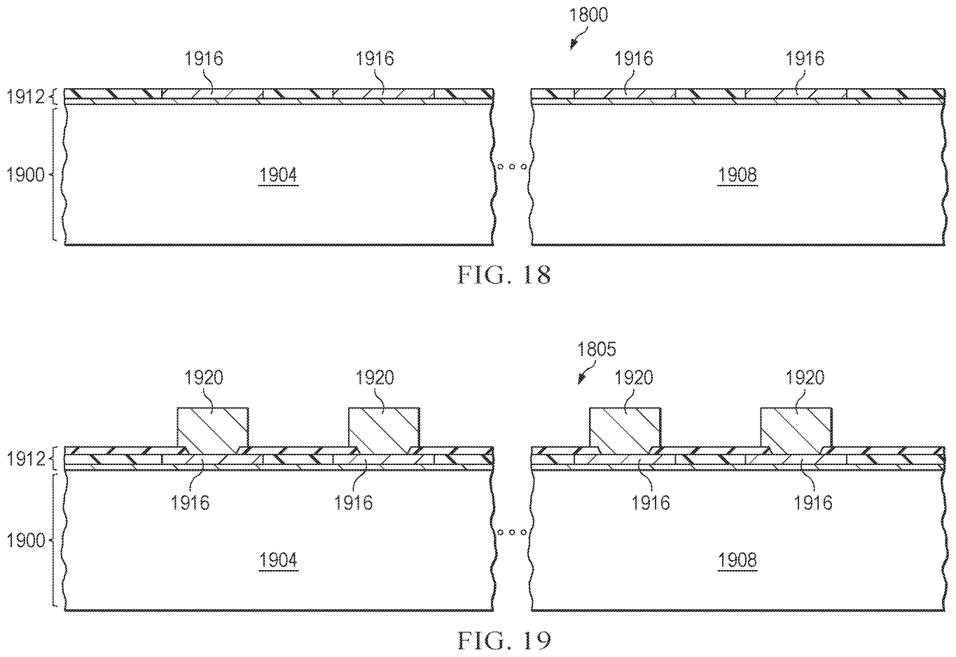

FIGS. 18-25 illustrates stages of another method for fabricating an IC package, such as the third example IC package 500 of FIG. 5. Thus, FIGS. 18-25 employ the same reference numbers to denote the same structures.

In a first stage 1800 of the method, as illustrated in FIG. 18, a wafer 1900 is provided. The wafer 1900 includes G number of dies, including a first die 1904 and a Gth die 1908, where G is an integer greater than or equal to one. The G number of dies include circuitry to execute a specific operation.

The first die 1904 and the Gth die 1908 include a metTop layer 1912 formed thereon. The metTop layer 1912 is formed, for example, with PVD, CVD or electroplating and patterning and etching (e.g., with a photoresist). The metTop layer 1912 is formed of metal pads that include bond pads 1916 that are conductively coupled to internal circuits of the G number of dies, including the first die 1904 and the Gth die 1908.

In a second stage 1805 of the method, as illustrated in FIG. 19, ENEPIG (electroless nickel electroless palladium immersion gold) material 1920 coats the bond pads 1916 of the G number of dies, including the first die 1904 and the Gth die 1908. The ENEPIG material 1920 is a multi-layer surface finish to enhance reliability and solderability. To coat the bond pads 1916 with the ENEPIG material 1920, the metal pads of the metTop layer 1912 is cleaned and activated, followed by sequential plating of nickel, palladium, and gold. Nickel acts as a barrier layer, palladium prevents nickel oxidation and provides a bondable surface, and gold offers excellent conductivity and corrosion resistance.

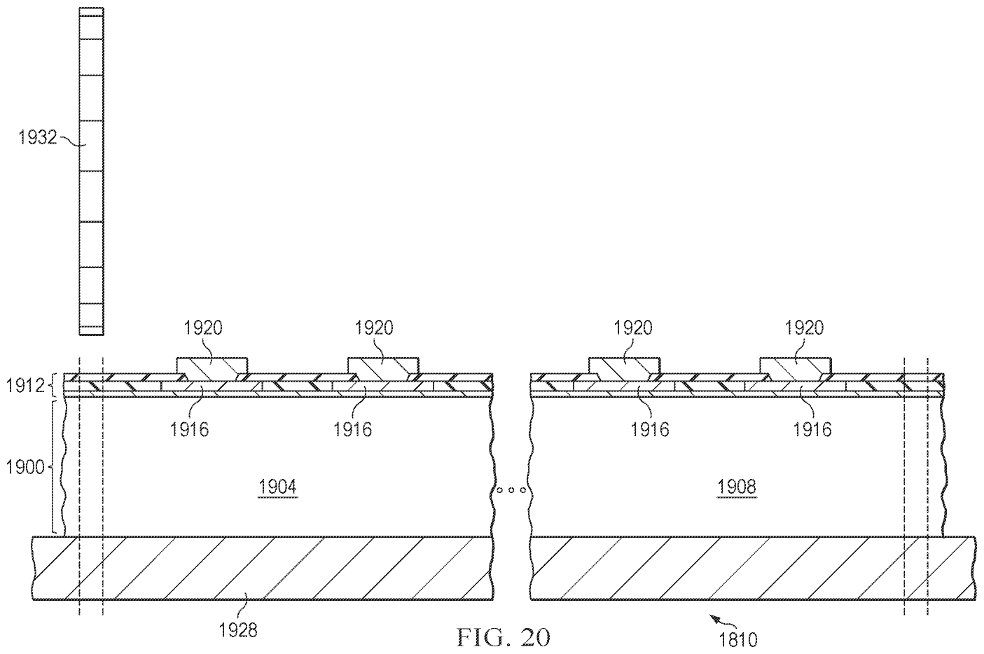

In a third stage 1810 of the method, as illustrated in FIG. 20, the wafer 1900 is placed on a dicing table 1928. Additionally, in the third stage 1810, a saw 1932, such as a laser saw, a diamond saw or a plasma cutter dices the wafer 1900 to singulate the G number of dies, including the first die 1904 and the Kth die 1908.

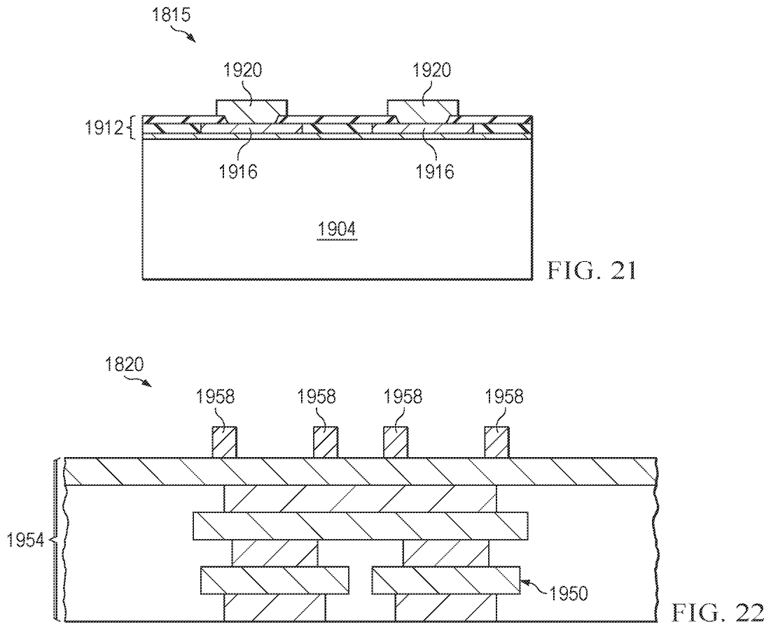

In a fourth stage 1815 of the method, as illustrated in FIG. 21, the first die 1904 is provided in response to the singulation. In a fifth stage 1820, as illustrated in FIG. 22, an interconnect 1950 is provided. The interconnect 1950 includes a substrate 1954 with pads. The substrate 1954 provides a planer surface. Additionally, the interconnect 1950 includes studs 1958 that extend in a direction normal from the planer surface of the substrate 1954. In examples such as the third example, the studs 1958 encircle a pad and form a cavity.

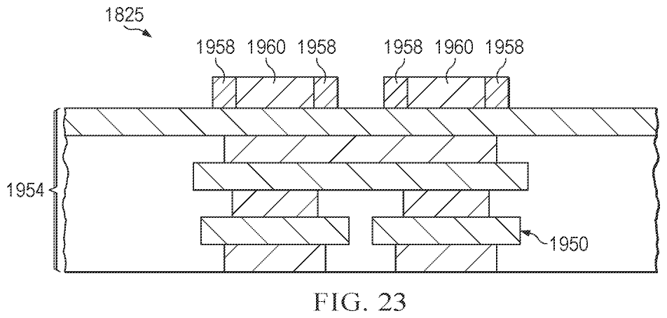

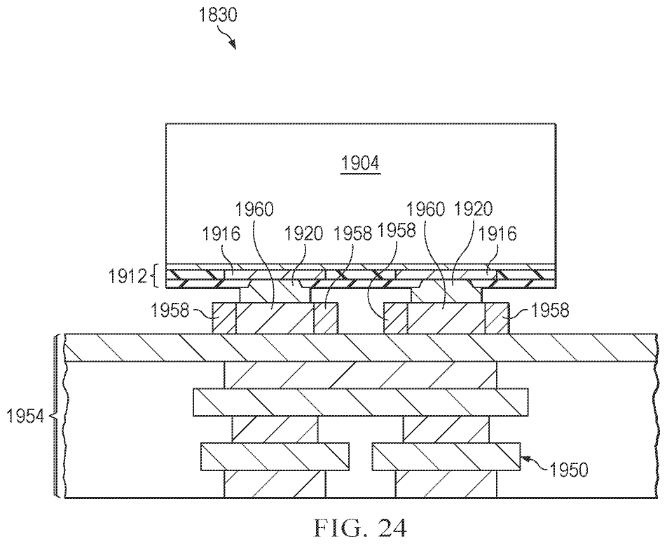

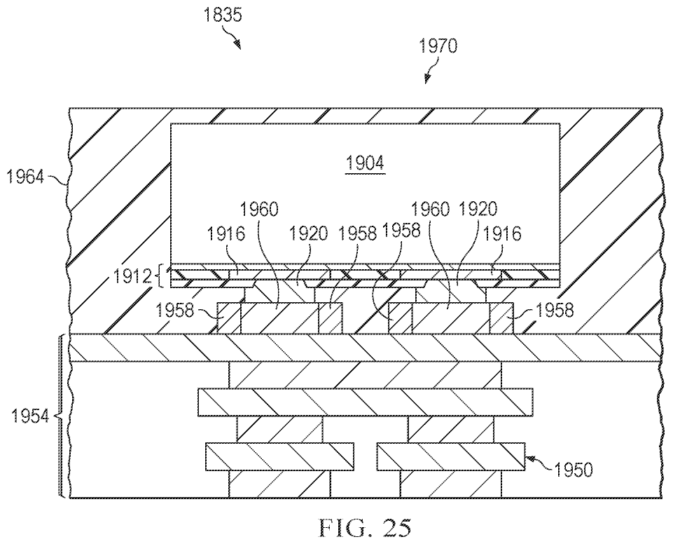

In a sixth stage 1825 of the method, as illustrated in FIG. 23, solder 1960 (e.g., solder paste) fills the cavities formed by the studs 1958, thereby forming solder reservoirs. In a seventh stage 1830 of the method, as illustrated in FIG. 24, the ENEPIG material 1920 is mounted on the solder 1960 filling the cavities. More particularly, the ENEPIG material 1920 overlaying the bond pads 1916 is attached to the solder 1960 overlaying the substrate 1954 (e.g., on pads of the substrate 1954). In some examples, the solder 1960 is reflowed to adhere the bond pads 1916 to the substrate 1954.

In an eighth stage 1835 of the method, as illustrated in FIG. 25, a mold compound 1964 is flowed over the first die 1904, the ENEPIG material 1920 and the interconnect 1950 in a mold flow operation. The mold compound 1964 encapsulates the first die 1904, the ENEPIG material 1920 and a portion of the interconnect 1950, leaving leads exposed. This forms an IC package 1970, which is employable to implement the third example IC package 500 of FIG. 5. Thus, in some examples, the IC package 1970 is a QFN IC package. The studs 1958 prevent spreading of a crack to avoid delamination of layers in the IC package 1970.

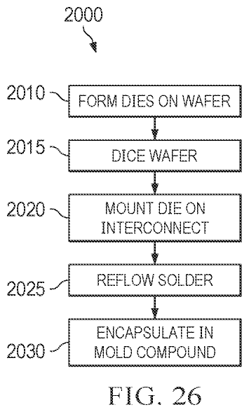

FIG. 26 illustrates a flowchart of an example method 2000 for forming an IC package, such as the IC package 100 of FIG. 1, the IC package 300 of FIG. 3, the IC package 500 of FIG. 5 or the IC package 700 of FIG. 7. At block 2010, dies are formed on a wafer (e.g., the wafer 1200 of FIG. 13). The dies include bond pads for forming copper posts (e.g., as discussed with respect to the first example, the second example and the fourth example) or for coating with ENEPIG material (e.g., as discussed with respect to the third example). At block 2015, the wafer is diced to singulate the dies (e.g., the die 112 of FIG. 1).

At block 2020 a die (provided from the singulation) with bond pads is mounted on an interconnect (e.g., the interconnect 104 of FIG. 1). The interconnect has a substrate having a planar surface with pads and studs (e.g., the studs 108 of FIG. 1) extending in a direction normal to the planar surface. The die is mounted such that the bond pads are coupled to the pads of the substrate. Moreover, in some examples, the bond pads are between at least two studs of the studs of the interconnect.

At block 2025, solder overlaying the pads of the substrate is reflowed. In examples such as the first example, the second example and the fourth example, the solder is used to attach copper posts formed on the die to the substrate. In other examples, such as the third example, the solder fills a cavity formed by the studs, and the ENEPIG material coating the bond pads is attached to the solder. At block 2030, the die and a portion of the interconnect are encapsulated in a mold compound.

In this description, unless otherwise stated, “about” preceding a parameter means being within +/−10 percent of that parameter. Modifications are possible in the described embodiments, and other embodiments are possible, within the scope of the claims.

What is claimed is:

1. An IC (integrated circuit) package comprising:
an interconnect comprising:
a substrate having a planar surface with pads; and
studs extending in a direction normal to the planar surface;
a die having bond pads coupled to the pads of the substrate; and
mold compound encapsulating the substrate, the die and a portion of the interconnect.

2. The IC package of claim 1, wherein the die comprises copper posts extending from the bond pads of the die.

3. The IC package of claim 2, wherein the pads of the interconnect comprise elevated traces extending from the planar surface to the copper posts of the die, and the elevated traces and the copper posts are attached with solder paste.

4. The IC package of claim 2, wherein the copper posts extend to the pads of the substrate, and the copper posts are attached to the pads of the substrate with solder paste.

5. The IC package of claim 2, wherein the studs are proximate a periphery of the interconnect.

6. The IC package of claim 5, wherein multiple copper posts are between a set of two or more studs of the interconnect.

7. The IC package of claim 1, wherein the studs form a cavity for solder to couple the pads of the interconnect to the bond pads of the die.

8. The IC package of claim 1, wherein the bond pads of the die are coated with ENEPIG (electroless nickel electroless palladium immersion gold) material.

9. The IC package of claim 1, wherein the IC package is a quad flat no-leads (QFN) IC package.

10. An IC (integrated circuit) package comprising:
an interconnect comprising:
a substrate having a planar surface with pads; and
elevated traces extending from the planar surface;
a die comprising bond pads;
copper posts extending from the bond pads of the die to the elevated traces and the copper posts; and
mold compound encapsulating die, the copper posts and a portion of the interconnect.

11. The IC package of claim 10, wherein the interconnect further comprises studs extending from the planar surface of the die.

12. The IC package of claim 11, wherein the bond pads are between at least two studs of the studs of the interconnect.

13. The IC package of claim 10, wherein the copper posts are circular and have a first diameter, and the elevated traces are circular and have a second diameter, the second diameter being greater than the first diameter.

14. The IC package of claim 13, wherein the elevated traces extend at least 25 micrometers beyond an edge of the bond pads.

15. The IC package of claim 10, wherein the copper posts are attached to the elevated traces with solder paste.

16. A method for forming an IC (integrated circuit) package comprising:
mounting a die with bond pads on an interconnect, the interconnect comprising:
a substrate having a planar surface with pads;
studs extending in a direction normal to the planar surface, wherein the die is mounted such that the bond pads are coupled to the pads of the substrate, wherein the bond pads are between at least two studs of the studs of the interconnect;
reflowing solder overlaying the pads of the substrate; and
encapsulating the die and a portion of the interconnect in a mold compound.

17. The method of claim 16, wherein the die comprises copper posts extending from the bond pads of the die.

18. The method of claim 17, wherein the pads of the interconnect comprise elevated traces extending from the planar surface to the copper posts of the die, and the elevated traces and the copper posts are attached with the solder.

19. The method of claim 17, wherein the copper posts extend to the pads of the substrate, and the copper posts are attached to the pads of the substrate with the solder.

20. The method of claim 17, further comprising filling cavities overlaying the pads of the substrate with solder, wherein the cavities are formed with the studs with the solder.
